(19) United States
(12) Patent Application Publication
(10) Pub. No.: US 2009/0239381 A1
(43) Pub. Date: Sep. 24, 2009

(54) POROUS FILM

(76) Inventors: Taisei Nishimi, Kanagawa (JP); Kenichi Ishizuka, Kanagawa (JP)

Correspondence Address: BIRCH STEWART KOLASCH & BIRCH, PO BOX 747, FALLS CHURCH, VA, 22040-0747, US

(21) Appl. No.: 12/405,755

(22) Filed: Mar. 17, 2009

(30) Foreign Application Priority Data
Mar. 18, 2008 (JP) 2008-069975

(51) Int. Cl. H01L 21/311; B32B 3/26; H01L 21/308; B05D 5/12

(52) U.S. Cl. 438/694; 428/314.2; 438/689; 427/245; 428/304.4

(57) ABSTRACT

A porous film which is formed using a block copolymer composed of a water-soluble polymer and a water-insoluble polymer, has nanometer-size pores, and in which a desired functional polymer is present on the pore inner walls is provided. The porous film includes a microphase-separated morphology including a continuous phase which is composed primarily of a water-insoluble polymer A, and a plurality of cylindrical microdomains which are composed primarily of a water-soluble polymer B incompatible with the water-insoluble polymer A, distributed within the continuous phase and oriented perpendicular to a surface of the film. The cylindrical microdomains contain therein pores having a cylindrical shape and an average diameter of between 1 and 200 nm.

### BACKGROUND OF THE INVENTION

The present invention relates to a porous film and a method of manufacture thereof. More particularly, the invention relates both to a porous film in which a layer of a specific polymer is present on the inner walls of the pores, and to a method of manufacturing such a porous film.

Recently, there has been a growing interest in structures having a controlled morphology at very small, nanometer-level, sizes (pore diameter and width, film thickness, etc.). Of these, structures containing nanometer size pores, especially structures in which the pores are in an ordered array (e.g., porous films), are thought to have potential applications in, for example, magnetic recording media, solar cells, light-emitting devices and separation membranes. In addition, because it is anticipated that functionalizing the interior of the pores in such structures will lead to the creation of materials having unprecedented capabilities, structures of this type are expected to serve as important materials in leading-edge fields such as energy, the environment and the life sciences.

Technology for the fabrication of structures having uniform pores about 100 nm or smaller in size include mesoporous silica synthesized using a surfactant as the template (C. T. Kresge et al.: “Ordered mesoporous molecular sieves synthesized by a liquid crystal template mechanism,” Nature 359, 710 (1992)), and anodized alumina (H. Masuda et al.: “Ordered metal nanohole arrays made by a two-step replication of honeycomb structures of anodic alumina,” Science 268, 1466 (1995)). A characteristic of anodized alumina in particular is that the pores have very uniform diameters. However, in both above cases, because the structures obtained are made of inorganic compounds, they are hard and brittle and thus lack flexibility, limiting their practical applications. Moreover, fabrication in a defect-free state over a large surface area is essentially quite difficult. Also, because the pore diameters are very small, covering the pore inner walls, etc. with a specific functional compound by a chemical process has proven to be a challenge.

At the same time, it is known that a block copolymer made of a polymer component A bonded with a polymer component B forms by self-assembly a microphase-separated morphology having an ordered nanopattern. When the block copolymer is dissolved in a suitable solvent and coated onto a workpiece, it is possible to easily form over a large surface area a film having a regularly arrayed pattern thereon. This has been the subject of a number of investigations.

For example, it has been reported that using a block copolymer composed of polyethylene glycol and a methacrylic acid ester polymer having liquid crystalline side chains results in the formation of a cylindrical morphology oriented perpendicular to the film surface forms (JP 3979470 B). In addition, it has been reported that when a polymethyl methacrylate homopolymer is added to a block copolymer composed of polystyrene/polymethyl methacrylate, cylindrical microdomains are oriented perpendicular to the substrate over a wide area (U. Jeong et al.: “Enhancement in the orientation of the microdomain in block copolymer thin films upon the addition of homopolymer,” Adv. Mater. 16, 533 (2004); S. Y. Yang et al.: “Nanoporous membranes with ultrahigh selectivity and flux for the filtration of virus,” Adv. Mater. 18, 709 (2006)). Also, L. Huang et al. (“Controlled microphase separated morphology of block polymer thin film and an approach to prepare inorganic nanoparticles,” Applied Surface Science 225, 39 (2004)) disclose the formation of a microphase-separated morphology using an amphiphilic block copolymer composed of polystyrene and polyethylene oxide. In particular, Yang et al. (2006) disclose that by using acetic acid to remove the polymethyl methacrylate homopolymer from the film that forms, a porous film having nanometer level pores can be obtained.

### SUMMARY OF THE INVENTION

However, in JP 3979470 B, because the block copolymer that is used must have a special, liquid-crystalline, structure, this approach has poor general utility, limiting application to other polymers. Also, in Jeong (2004) and Yang (2006), although a porous film having micropores is obtained, in each case the block copolymer used is only one of a specific type composed of polymers which are both hydrophobic. In Huang (2004) which uses an amphiphilic block copolymer, only the ethylene glycol portion of the water-soluble polymer selectively adsorbs to the substrate; a microphase-separated morphology having a regularly arrayed pattern is not obtained.

Hence, when a block copolymer composed of a water-soluble (hydrophilic) polymer and a water-insoluble (hydrophobic) polymer is used, the components within the polymer are completely different in nature, making it difficult to obtain a microphase-separated morphology of controlled orientation. Not enough is known at present.

Also, in order to obtain structures having nanometer-size pores, attempts are being made to use processes such as ion beam etching to remove only the cylindrical domains in a cylindrical morphology obtained from a block copolymer. However, such processes damage not only the cylindrical domains but the structure as a whole, resulting in the formation of pores of variable size and a loss in the orderliness of the pore array. Moreover, when surface modification such as hydrophilization of the inner walls of the resulting pores is attempted, because the pores are very small in size, surface modification fails to proceed to a sufficient degree. Even when such modification is possible, the surface-modified layer has a tendency to delaminate.

It is therefore an object of the present invention to provide a porous film which is formed using a block copolymer composed of a water-soluble polymer and a water-insoluble polymer, has nanometer-size pores, and in which a desired functional polymer, particularly a water-soluble polymer, is present on the pore inner walls. Another object of the invention is to provide a method which is capable of easily manufacturing such a porous film over a large surface area.

Focusing on the affinity between a substrate and a block copolymer composed of a water-soluble polymer and a water-insoluble polymer, the inventors have created thin-films from mixtures of a block copolymer composed of a water-soluble polymer and a water-insoluble polymer with a water-soluble homopolymer, and closely studied the phase separation behavior in the films on various types of substrates having differing surface free energies. As a result, they have discovered that when a substrate having a specific surface free energy—namely a substrate having a relatively high hydrophobicity—is used, cylindrical microdomains that are perpendicularly oriented to the substrate are selectively formed. The inventors have also found that rinsing the thin-film with water removes only the water-soluble homopolymer, resulting in the formation of pores having a cylindrical shape that pass entirely through the film surface.

That is, the inventors have found that the above objects of the invention are resolved by the following porous films and porous film manufacturing methods.
[1] A porous film comprising a microphase-separated morphology comprising a continuous phase which is composed primarily of a water-insoluble polymer A, and a plurality of cylindrical microdomains which are composed primarily of a water-soluble polymer B incompatible with the water-insoluble polymer A, distributed within the continuous phase and oriented perpendicular to a surface of the film, wherein the cylindrical microdomains contain therein pores having a cylindrical shape and an average diameter of between 1 and 200 nm.
[2] The porous film of [1], wherein the pores have a density of between 2 and 2,500 pores/μm².
[3] The porous film of [1], wherein the water-soluble polymer B is a biocompatible polymer.
[4] The porous film of [1], wherein the water-insoluble polymer A is selected from among polystyrenes, poly(meth)acrylates, polybutadienes and polyisoprenes.
[5] The porous film of [1], wherein the porous film is adapted for use as a mask in an etching operation of a substrate.
[6] A method of manufacturing the porous film of [1], the method comprising the steps of, in order: (1) forming a film by coating a substrate surface having a contact angle with water of between 40° and 110° with a solution containing (a) a block copolymer composed of a water-insoluble polymer A and a water-soluble polymer B which are mutually incompatible and (b) a water-soluble homopolymer B′, which film satisfies the following formulas (1) and (2)

5<M(b1)/M(b2)<250 (1)

0.60≦a1/(a1+b1+b2)≦0.90 (2),

where M(b1) represents the weight-average molecular weight of the water-soluble polymer B of the block copolymer, M(b2) represents the weight-average molecular weight of the water-soluble homopolymer B′, a1 represents the volume of the water-insoluble polymer A of the block copolymer in the film, b1 represents the volume of the water-soluble polymer B of the block copolymer in the film and b2 represents the volume of the water-soluble homopolymer B′ in the film; and (2) removing the water-soluble homopolymer B′ within the film with water.
[7] The method of [6], wherein the solution has a combined concentration of the block copolymer and the water-soluble homopolymer B′, based on the total weight of the solution, of between 0.1 and 20 wt %.
[8] A porous film obtained by a method comprising the steps of, in order: (1) forming a film by coating a substrate surface having a contact angle with water of between 40° and 110° with a solution containing (a) a block copolymer composed of a water-insoluble polymer A and a water-soluble polymer B which are mutually incompatible and (b) a water-soluble homopolymer B′, which film satisfies the following formulas (1) and (2)

5<M(b1)/M(b2)<250 (1)

0.60≦a1/(a1+b1+b2)≦0.90 (2),

where M(b1) represents the molecular weight of the water-soluble polymer B of the block copolymer, M(b2) represents the molecular weight of the water-soluble homopolymer B′, a1 represents the volume of the water-insoluble polymer A of the block copolymer in the film, b1 represents the volume of the water-soluble polymer B of the block copolymer in the film and b2 represents the volume of the water-soluble homopolymer B′ in the film; and (2) removing the water-soluble homopolymer B′ within the film with water.
[9] A method of manufacturing a substrate having recessed features on a surface thereof, the method comprising the steps of, in order: (1) forming the porous film of [1] on a substrate, (2) etching the substrate using the porous film as a mask so as to form recessed features on a surface of the substrate, and (3) removing the porous film remaining on the substrate.
[10] The method of [9], wherein the substrate is a quartz substrate or a semiconductor substrate.

Accordingly, the present invention provides a porous film which is formed using a block copolymer composed of a water-soluble polymer and a water-insoluble polymer, which has nanometer-size pores, and in which a desired functional polymer, particularly a water-soluble polymer, is present on the pore inner walls. The invention also provides a method which is capable of easily manufacturing such a porous film over a large surface area.

The invention further provides a method of manufacturing a substrate having recessed features thereon by using such a porous film as a mask during etching.

### BRIEF DESCRIPTION OF THE DRAWINGS

In the accompanying drawings:

FIG. 1A is a perspective, cross-sectional view showing an applied film according to one embodiment of the invention, and FIG. 1B is a top view of the same;

FIG. 2A is a perspective, cross-sectional view showing a porous film according the invention, and FIG. 2B is a top view of the same;

FIG. 3A is an atomic force micrograph taken from the top side of Sample 1, and FIG. 3B is a scanning electron micrograph of a fracture plane of Sample 1;

FIG. 4 is an atomic force micrograph taken from the top side of Sample 2;

FIG. 5 is an atomic force micrograph taken from the top side of Sample 3;

FIG. 6 is a scanning electron micrograph of a fracture plane of Sample 4;

FIG. 7 is an atomic force micrograph taken from the top side of Sample 6;

FIG. 8 is an atomic force micrograph taken from the top side of Sample 7;

FIG. 9 is an atomic force micrograph taken from the top side of Sample 8;

FIG. 10 is an atomic force micrograph taken from the top side of Sample 10;

FIG. 11 is an atomic force micrograph taken from the top side of Sample 11;

FIG. 12 is an atomic force micrograph taken from the top side of Sample 12;

FIG. 13A is an atomic force micrograph of the exposed surface side of Sample 3 delaminated from the substrate, and FIG. 13B is an atomic force micrograph of the substrate side of Sample 3 delaminated from the substrate;

FIGS. 14A to C are schematic cross-sectional diagrams of a substrate and a porous film which show the sequence of steps in a method of manufacturing a substrate having recessed features on the surface;

FIG. 15 is an atomic force micrograph taken from the top side of Sample 14;

FIG. 16 is a scanning electron micrograph of Sample 14;

FIG. 17 is an atomic force micrograph taken from the top side of Substrate 1;

FIG. 18 is an atomic force micrograph taken from the top side of Substrate 2; and

FIG. 19 is an atomic force micrograph taken from the top side of Substrate 3.

### DETAILED DESCRIPTION OF THE INVENTION

Specific embodiments of the invention are described below.

The porous film of the invention has a microphase-separated morphology containing a continuous phase which is composed primarily of a water-insoluble polymer A, and a plurality of cylindrical microdomains which are composed primarily of a water-soluble polymer B incompatible with the water-insoluble polymer A, distributed within the continuous phase and oriented perpendicular to a surface of the film. The cylindrical microdomains serving as the dispersed phase contain therein pores having a cylindrical shape and an average pore size of between 1 and 200 nm.

First, the materials (block copolymer, water-soluble homopolymer) used to manufacture the porous film of the invention are described below, following which the method of manufacture and the porous film itself are described.

### Block Copolymer

The block copolymer according to the invention is a polymer formed by chemical bonding between a water-insoluble polymer A and a water-soluble polymer B which is incompatible with the water-insoluble polymer A. The block copolymer may be in the form of a diblock copolymer, a triblock copolymer or a multiblock copolymer. Specifically, referring to a portion composed of water-insoluble polymer A as an “A block” and a portion composed of water-insoluble polymer B as a “B block,” exemplary block copolymers include A-B type block copolymers having an -A-B- structure and composed of one A block bonded with one B block, A-B-A type block copolymers having an -A-B-A- structure and composed of A blocks bonded to both ends of a B block, and B-A-B type block copolymers having a -B-A-B- structure and composed of B blocks bonded to both ends of an A block. In addition, use may also be made of block copolymers having an -(A-B)ₙ- structure and composed of a plurality of A blocks and B blocks. Of these, from the standpoint of availability and ease of synthesis, A-B type block copolymers (diblock copolymers) are preferred. The chemical bonds connecting the polymers to each other are preferably covalent bonds, and most preferably carbon-carbon bonds.

Block copolymers are known to differ from random copolymers in that, for example, they form a structure wherein a phase A of aggregated polymer A chains and a phase B of aggregated polymer B chains are spatially separated (microphase-separated morphology). In the phase separation (macrophase separation) obtained with ordinary polymer blends, because the two types of polymer chains can be completely separated, complete separation into two phases is ultimately achieved, resulting in a unit cell size of at least 1 μm. By contrast, the unit cells in the microphase-separated morphologies that can be obtained with a block copolymer have a size on the order of from several nanometers to several deca-nanometers. Moreover, depending on the composition of the blocks therein, the microphase-separated morphologies are known to exhibit a variety of configurations, such as spherical micellar, cylindrical or lamellar morphologies.

In the present invention, “water-insoluble polymer A” is defined as a polymer having a polymer solubility in 100 g of distilled water at 25° C. of 1 g or less. Polymers having a polymer solubility in 100 g of distilled water at 25° C. of 1 g or less may be selected for use from among those mentioned in, for example, paragraphs [0061] to [0069] of JP 11-15091 A or in Polymer Handbook Fourth Edition, Volumes 1 & 2 (by J. Brandrup, E. H. Immergut, E. A. Grulke, et al.; published by Interscience; chapter VII, pp. 499-532).

Of these, polyalkylenes, polyvinyl esters, polyvinyl halides, polystyrenes, poly(meth)acrylates, polysiloxanes, polyesters, polybutadienes and polyisoprenes are preferred in terms of the ease of synthesizing a polymer of uniform molecular weight. From the standpoint of having a glass transition temperature higher than room temperature, polystyrenes (e.g., polystyrene, polymethylstyrene, polydimethylstyrene, polytrimethylstyrene, polyethylstyrene, polyisopropylstyrene, polychloromethylstyrene, polymethoxystyrene, polyacetoxystyrene, polychlorostyrene, polydichlorostyrene, polybromostyrene, polytrifluoromethylstyrene), poly(meth)acrylates (e.g., polymethyl(meth)acrylate, polyethyl(meth)acrylate, polybutyl(meth)acrylate, polyhexyl(meth)acrylate, poly-2-ethylhexyl(meth)acrylate, polyphenyl(meth)acrylate, polymethoxyethyl(meth)acrylate, polyglycidyl(meth)acrylate), polybutadienes (e.g., 1,2-polybutadiene, 1,4-polybutadiene) and polyisoprenes (e.g., polyisoprene) are even more preferred. Polystyrene, polymethyl methacrylate, 1,4-polybutadiene and polyisoprene are especially preferred.

The weight-average molecular weight (Mw) of the water-insoluble polymer A in the block copolymer is suitably selected based on the size of the pores in the porous film to be obtained and the relationship with the molecular weight of the subsequently described water-soluble homopolymer B′, and is preferably between 1.0×10⁴ and 1.0×10⁶, and more preferably between 5.0×10⁴ and 5.0×10⁵. Within the above range, the water-insoluble polymer A readily dissolves within the solvent at the time of porous film production, in addition to which the pore array obtained is more highly ordered.

The above weight-average molecular weight (Mw) is the polystyrene-equivalent weight-average molecular weight obtained by measurement using gel permeation chromatography (GPC).

In the present invention, “water-soluble polymer B” is defined as a polymer having a polymer solubility in 100 g of distilled water at 25° C. of more than 1 g. Polymers having a polymer solubility in 100 g of distilled water at 25° C. of more than 1 g may be selected for use from among those mentioned in, for example, paragraphs [0038] to [0053] of JP 2005-10752 A or Polymer Handbook Fourth Edition, Volumes 1 & 2 (by J. Brandrup, E. H. Immergut, E. A. Grulke, et al.; published by Interscience; chapter VII; pp. 499-532).

Of these, from the standpoint of synthesizing polymer having a uniform molecular weight, carboxyl group-containing polymers and their salts, sulfonic acid group-containing polymers and their salts, phosphoric acid group-containing polymers and their salts, phosphorylcholine group-containing polymers, amino group-containing polymers (e.g., polyallylamine, polyethyleneimine), amide group-containing polymers and ether group-containing polymers are preferred.

Ether-containing polymers (e.g., polymethyl vinyl ether, polyalkylene glycols such as polyethylene glycol, polyethylene glycol monoethyl ether(meth)acrylate) and phosphorylcholine group-containing polymers (e.g., poly-2-methacryloxyethylphosphorylcholine, poly-4-(meth)acryloxybutylphosphorylcholine, poly-6-(meth)acryloxyhexylphosphorylcholine) are more preferred. Biocompatible polymers, such as polyethylene glycol, and phosphorylcholine group-containing polymers (also called “MPC polymers”) are preferred on account of their high protein adsorption suppressing ability and their suitability for use as a membrane for protein separation. Polyethylene glycol is especially preferred because of the availability of the starting material.

The weight-average molecular weight (Mw) of the water-soluble polymer B in the block copolymer is suitably selected based on the size of the pores in the porous film to be obtained and the relationship with the molecular weight of the subsequently described water-soluble homopolymer B′, and is preferably between 1.0×10³ and 1.0×10⁵, and more preferably between 5.0×10³ and 5.0×10⁴. Within the above range, the water-soluble polymer B readily dissolves within the solvent at the time of porous film production, in addition to which the pore array obtained is more highly ordered.

The above weight-average molecular weight (Mw) is the polystyrene-equivalent weight-average molecular weight obtained measurement using gel permeation chromatography (GPC).

The block copolymer of the invention is composed of the mutually incompatible water-insoluble polymer A and water-soluble polymer B, and is synthesized by combining the respective polymers described above. Preferred forms of the block copolymer include block copolymers in which the water-insoluble polymer A is polystyrene and the water-soluble polymer B is polyethylene glycol, block copolymers in which the water-insoluble polymer A is polybutadiene and the water-soluble polymer B is polyethylene glycol, and block copolymers in which the water-insoluble polymer A is polymethyl methacrylate and the water-soluble polymer B is poly(2-methacryloxyethylphosphorylcholine). Of these, a block copolymer of polystyrene and polyethylene glycol is especially preferred on account of its excellent protein adsorption suppressing ability and its suitability for use as a membrane for protein separation.

The weight-average molecular weight (Mw) of the block copolymer of the invention is suitably selected based on the size of the pores in the porous film to be obtained and the relationship with the molecular weight of the subsequently described water-soluble homopolymer B′, and is preferably between 1.0×10⁴ and 1.1×10⁶, and more preferably between 5.5×10⁴ and 5.5×10⁵. Within the above range, the block copolymer readily dissolves within the solvent at the time of porous film production, in addition to which the pore array obtained is more highly ordered.

The above weight-average molecular weight (Mw) is the polystyrene-equivalent weight-average molecular weight obtained by measurement using gel permeation chromatography (GPC).

The block copolymer of the present invention preferably has a narrow molecular weight distribution. Specifically, the molecular weight distribution (Mw/Mn) expressed in terms of the weight-average molecular weight (Mw) and the number-average molecular weight (Mn) is preferably between 1.00 and 1.30, and more preferably between 1.00 and 1.15. By having the Mw/Mn value fall within the above range, a microphase-separated morphology of more uniform size can be formed.

The copolymerization ratio of the block copolymer in the invention is suitably selected so as to satisfy subsequently described formulas (1) and (2) and so as to enable a cylindrical microphase-separated morphology to be obtained. The volumetric copolymerization ratio expressed as water-insoluble polymer A/water-soluble polymer B is preferably between 0.9/0.1 and 0.65/0.35, and more preferably between 0.8/0.2 and 0.7/0.3. Within the above range, a cylindrical microphase-separated morphology having a more highly order array can be obtained.

The block copolymer of the invention can be synthesized by a known method. Examples of methods that may be employed for this purpose include living anionic polymerization, living cationic polymerization, living radical polymerization, group transfer polymerization and ring-opening metathesis polymerization (Nikos Hadjichristidis et al.: Block Copolymers: Synthetic Strategies, Physical Properties, and Applications (Wiley-Interscience, 2002)). Use may also be made of commercial product manufactured by Polymer Source, Inc.

### Water-Soluble Homopolymer B′

The water-soluble homopolymer B′ of the present invention is a polymer having the same constituent monomers as the water-soluble polymer B in the above-described block copolymer. The definition of the water-soluble homopolymer B′ is identical to that of the water-soluble polymer B in the above-described block copolymer.

The weight-average molecular weight (Mw) of the water-soluble homopolymer B′ of the invention is suitably selected based on the size of the pores in the porous film to be obtained and the relationship with the molecular weight of the above about 50 and 1.0×10⁴, and more preferably between 50 and 5.0×10³.

The above weight-average molecular weight (Mw) is the polystyrene-equivalent weight-average molecular weight obtained by measurement using gel permeation chromatography (GPC).

The water-soluble homopolymer B′ of the present invention preferably has a narrow molecular weight distribution. Specifically, the molecular weight distribution (Mw/Mn) expressed in terms of the weight-average molecular weight (Mw) and the number-average molecular weight (Mn) is preferably between 1.0 and 3.0, and more preferably between 1.0 and 1.5. By having the Mw/Mn value fall within the above range, a microphase-separated morphology of more uniform size can be formed.

### Formula (1)

Next, the relationship between the molecular weight of the block copolymer composed of water-insoluble polymer A and water-soluble polymer B and the molecular weight of the water-soluble homopolymer B′ which are used in the invention is described. In the present invention, the block copolymer and the water-soluble homopolymer B′ satisfy formula (1) below.

5<M(b1)/M(b2)<250 (1)

In formula (1), M(b1) represents the weight-average molecular weight of the water-soluble polymer B in the block copolymer, and M(b2) represents the weight-average molecular weight of the water-soluble homopolymer B′.

If the above M(b1)/M(b2) value is 5 or less, the block copolymer and the water-soluble homopolymer B′ phase-separate at a micrometer level, and a microphase-separated morphology having the desired degree of order may not be attainable. On the other hand, if this value is 250 or more, the water-soluble homopolymer B′ has too small a molecular weight and, instead of functioning as a polymer, behaves like a water-soluble low-molecular-weight compound, making it difficult to control the pore size of the resulting porous film.

To further improve the degree of order of the microphase-separated morphology obtained, it is more preferable for the ratio M(b1)/M(b2) to satisfy the following condition: 10<M(b1)/M(b2)<200.

### Formula (2)

Next, the mixing ratio between the block copolymer, which is composed of water-insoluble polymer A and water-soluble polymer B, and the water-soluble homopolymer B′ is described. In the present invention, the block copolymer and the water-soluble homopolymer B′ satisfy formula (2) below

0.60≦a1/(a1+b1+b2)≦0.90 (2)

In formula (2), a1 represents the volume of the water-insoluble polymer A of the block copolymer in the film, b1 represents the volume of the water-soluble polymer B of the block copolymer in the film and b2 represents the volume of the water-soluble homopolymer B′ in the film.

If the above a1/(a1+b1+b2) value is smaller than 0.60, the microphase-separated morphology becomes a lamellar morphology, making it impossible to obtain the desired cylindrical morphology. On the other hand, if the a1/(a1+b1+b2) value is larger than 0.90, the water-soluble polymer B will assume a spherical morphology within the water-insoluble polymer A component, making it impossible to obtain the desired cylindrical morphology. The volumes are derived by using the densities and weights of the respective polymers. The densities used for the respective polymers are the values cited in, for example, Polymer Handbook Fourth Edition, Volume 2, by J. Brandrup, E. J. Immergut and E. A. Grulke (John Wiley & Sons, Inc.; 1999).

When the a1/(a1+b1+b2) value is between 0.60 and 0.90, microphase separation having a cylindrical morphology is formed by the block copolymer and the water-soluble homopolymer B′. More specifically, the cylindrical domains within the microphase separated morphology are composed of the water-soluble polymer B in the block copolymer and the water-soluble homopolymer B′, and are oriented perpendicular to the film surface. On passing through the subsequently described water rinsing treatment, the water-soluble homopolymer B′ is selectively removed, thereby giving the desired porous film having a plurality of pores of cylindrical shape that are oriented perpendicular to the film surface.

To further enhance the degree of order of the resulting microphase-separated morphology, it is more preferable for the ratio a1/(a1+b1+b2) to satisfy the following condition:

0.70≦a1/(a1+b1+b2)≦0.85.

### Substrate

Next, the substrate on which a mixed thin-film of the block copolymer and the water-soluble homopolymer B′ is to be deposited is described. The substrate used in the present invention is a substrate whose surface has a contact angle with water of between 40° and 110°, and preferably a substrate whose surface has a contact angle with water of between 50° and 105°. Illustrative examples include surface-modified quartz, polymer, glass and ceramic. “Contact angle” refers herein to the static contact angle, which is measured by the sessile drop method at 23° C. using a contact goniometer. As used herein, “static contact angle” refers to the contact angle under conditions where flow and other changes in state associated with time do not arise.

Because the blocks of the block copolymer composed of a water-soluble polymer and a water-insoluble polymer are completely different in nature, it has been exceeding difficult to control the orientation of the microphase-separated morphology. In connection with the present invention, the inventors have found that by focusing on the affinity between the substrate and the polymers and controlling the surface energy of the substrate surface within a specific range as described above, the degree of order of the microphase-separated morphology can be further enhanced.

In one preferred embodiment, the substrate is a substrate (particularly a quartz substrate) having a silane coupling agent layer on the surface; such a substrate enables the cylindrical morphology obtained by the perpendicular orientation of microdomains on the film surface to have a higher degree of order. A substrate having a silane coupling agent layer can be obtained by surface treating the substrate with a silane coupling agent.

Specifically, the silane coupling agent layer is formed by coating the substrate with a silane coupling agent and heating. Application of the silane coupling agent to the substrate may be carried out by a suitable method, such as dip coating, spin coating, spray coating or vapor phase deposition, using a liquid composed only of the silane coupling agent or a solution prepared by dissolving the silane coupling agent in an organic solvent. In the present invention, dip coating or spin coating is preferred. After coating, the resulting substrate may be rinsed with a suitable solvent or the like. Also, following coating with a silane coupling agent, heating may be suitably carried out. Heating is typically carried out with a heating means, such as a hot plate or a hot-air dryer, at a temperature of between 20 and 200° C., and preferably between 20 and 150° C.

### Silane Coupling Agent

The type of silane coupling agent used in the present invention is suitably selected. However, to further increase the orderliness of the microphase-separated morphology of the block copolymer layer, preferred use may be made of a silane coupling agent of general formula (1) below.

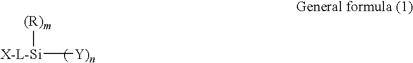

In the above formula (1), X is a functional group, L is a linkage group or merely a bond, R is a hydrogen atom or an alkyl of 1 to 6 carbons, and Y is a hydrolyzable group. Also, the letter m is an integer from 0 to 2 and the letter n is an integer from 1 to 3, such that n+m=3.

In general formula (1), X is a functional group, illustrative examples of which include a hydrogen atom and amino, carboxyl, hydroxyl, aldehyde, thiol, isocyanate, isothiocyanate, epoxy, cyano, hydrazino, hydrazide, vinylsulfone, vinyl, and alkyl (having preferably from 1 to 20 carbons, and more preferably from 6 to 18 carbons) groups. Of these, an alkyl group is preferred.

In general formula (1), R is a hydrogen atom or an alkyl of 1 to 6 carbons. Of these, methyl and ethyl are preferred. In cases where there are a plurality of R moieties in general formula (1), the R moieties may be the same or different.

In general formula (1), L may be a linkage group. Illustrative examples include alkylene groups (having preferably from 1 to 20 carbons, and more preferably from 2 to 10 carbons), —O—, —S—, arylene groups, —CO—, —NH—, —SO₂—, —COO—, —CONH— and groups that are combinations thereof. Of these, alkylene groups are preferred. In cases where L represents merely a bond, the X moiety in general formula (1) is directly linked to silicon.

In general formula (1), Y is a hydrolyzable group. Illustrative examples include alkoxy groups (e.g., methoxy, ethoxy), halogen atoms (e.g., fluorine, chlorine, bromine, iodine), and acyloxy groups (e.g., acetoxy, propanoyloxy). Of these, methoxy groups, ethoxy groups and chlorine atoms are preferred because of the good reactivity they confer.

In general formula (1), the letter m is an integer from 0 to 2 and the letter n is an integer from 1 to 3, such that n+m=3. The letter m is preferably 1 or 2, and the letter n is preferably 1 or 2.

Illustrative, non-limiting, examples of the silane coupling agent used in the invention include octadecyltrimethoxysilane, ethyldimethylchlorosilane, dimethylaminopropyltrimethoxysilane, diethylaminopropyltrimethoxysilane, chlorotrimethylsilane, dichlorodimethylsilane, phenyldimethylchlorosilane, perfluorodecyltriethoxysilane, p-methoxyphenylpropylmethyldichlorosilane, γ-aminopropyltrimethoxysilane, N-β(aminoethyl)-γ-aminopropyltrimethoxysilane, γ-aminopropylmethyldiethoxysilane, γ-mercaptopropyltrimethoxysilane and γ-glycidoxypropyltriethoxysilane.

In another preferred embodiment, the substrate is a substrate (particularly a quartz substrate) having a layer of polyhydroxystyrene or the like on the surface; such a substrate enables the cylindrical morphology achieved by the perpendicular orientation of microdomains on the film surface to have a higher degree of order. This layer is formed by a known method such as spin coating.

Such a layer of polyhydroxystyrene or the like acts as a release layer. Here, “release layer” refers to a layer provided between the porous film and the substrate. For example, by bringing the release layer into contact with a specific solvent which dissolves the layer, the porous film can easily be peeled from the substrate.

According to one preferred embodiment of the invention, the substrate has a layer of the silane coupling agent of above general formula (1) (preferably one where, in general formula (1), X is a methyl group and L is an alkylene group) thereon, the water-insoluble polymer A is a polystyrene polymer (preferably, polystyrene) and the water-soluble polymer B is a polyalkylene glycol (preferably, polyethylene glycol). With the foregoing combination, the cylindrical microphase-separated morphology has a further enhanced degree of order and the cylindrical domains are oriented substantially perpendicular to the film surface.

### Method of Manufacturing the Porous Film

The method of manufacturing the porous film of the invention, while not subject to any particular limitation, is preferably one which includes primarily the following two steps:
(1) forming a film by coating a substrate surface having a contact angle with water of between 40° and 110° with a solution containing (a) a block copolymer composed of a water-insoluble polymer A and a water-soluble polymer B which are mutually incompatible and (b) a water-soluble homopolymer B′, which film satisfies above formulas (1) and (2); and
(2) removing the water-soluble homopolymer B′ within the film with water.

Each step is described in detail below.

### Step 1

Step 1 is the step of forming a film by coating a substrate surface with a solution containing the above-described block copolymer and water-soluble homopolymer B′. By means of this step, a film having a microphase-separated morphology can be formed on a substrate.

The solvent used for preparing the solution containing the block copolymer and water-soluble homopolymer B′ should be one which dissolves the block copolymer, and is suitably selected according to both polymers. For example, a solvent which dissolves the block copolymer may be suitably selected from the solvents mentioned in Polymer Handbook Fourth Edition, Volumes 1 & 2 (J. Brandrup, E. H. Immergut, E. A. Grulke et al. (published by Interscience); chapter VII, pp. 266-285).

Exemplary solvents include alcohols, polyols, polyol ethers, amines, amides, heterocyclic compounds, sulfoxides, sulfones, esters, ethers, ketones, aliphatic hydrocarbons, aromatic hydrocarbons, nitriles and halogenated compounds. Of these, aromatic hydrocarbons (e.g., toluene, xylene, cumene), halogenated compounds (chloroform, dichloromethane, trichloroethane, carbon tetrachloride), amides (e.g., formamide, N,N-dimethylformamide, N,N-dimethylacetamide, N,N-diethyldodecanamide), ethers (e.g., tetrahydrofuran, diethyl ether), and ketones (e.g., methyl ethyl ketone, diethyl ketone, methyl isobutyl ketone, benzyl methyl ketone, benzyl acetone, diacetone alcohol, cyclohexanone, acetone, urea) are preferred. Toluene, chloroform, dichloromethane, dimethylformamide, tetrahydrofuran, methyl ethyl ketone and methyl isobutyl ketone are more preferred.

The combined concentration of the block copolymer and the water-soluble homopolymer B′ in the solution, based on the total weight of the solvent, is preferably between 0.1 and 20 wt %, and more preferably between 0.25 and 15 wt %. Within this range, handleability in the subsequently described coating operation is good, enabling a uniform film to be easily obtained. The above solvents may be used singly or in combination.

With regard to preferred combinations of the above solvent with the block copolymer and the water-soluble homopolymer B′, when the water-insoluble polymer A is polystyrene and the water-soluble polymer B is polyethylene glycol, the solvent is most preferably toluene or chloroform.

Optional ingredients (e.g., UV absorbers, antioxidants) may also be added to the solution containing the block copolymer and the water-soluble homopolymer B′, insofar as the objects of the invention are attainable.

The method of applying the above-described solution is not subject to any particular limitation, provided a uniform thickness and a smooth surface are achieved. Examples of methods that may be employed include spin coating, spray coating, roll coating and ink jet coating. Of these, spin coating is preferred from the standpoint of productivity.

The spin coating conditions are suitably selected according to the block copolymer used. After coating, a drying step may be carried out if necessary. The drying conditions for solvent removal are suitably selected according to the substrate employed and the block copolymer used, although it is preferable to carry out such treatment at a temperature of between 20° C. and 200° C. for a period of between 0.5 hour and 336 hours. The drying temperature is more preferably between 20° C. and 180° C., and even more preferably between 20° C. and 160° C. Such drying treatment may be carried out in several divided stages. Drying treatment is most preferably carried out in a nitrogen atmosphere, in low-concentration oxygen, or at an atmospheric pressure of 10 torr or less.

Following Step 1, if necessary, the applied film obtained in Step 1 may be subjected to heating treatment (heating step). The heating step further enhances the degree of order of the resulting microphase-separated morphology. The heating temperature and time are suitably selected according to such factors as the block copolymer used and the film thickness, although it is preferable for the heating temperature to be at or above the glass transition temperature of the above-described water-insoluble polymer A and water-soluble polymer B. For example, the heating temperature is preferably between 60 and 300° C., and more preferably between 80 and 270° C. If the heating temperature is too low, this step will have only a limited effect; on the other hand, if the heating temperature is too high, undesirable effects such as polymer decomposition may arise. The heating time is typically at least 10 seconds, preferably between 0.5 minutes and 1,440 minutes, and more preferably between 1 minute and 60 minutes. If the heating time is too short, this step will have only a limited effect; on the other hand, a heating time which is too long is not cost-effective because the intended effects of this step are already satisfied.

The present invention may be carried out in a vacuum, in an inert gas atmosphere, or in an organic solvent vapor atmosphere.

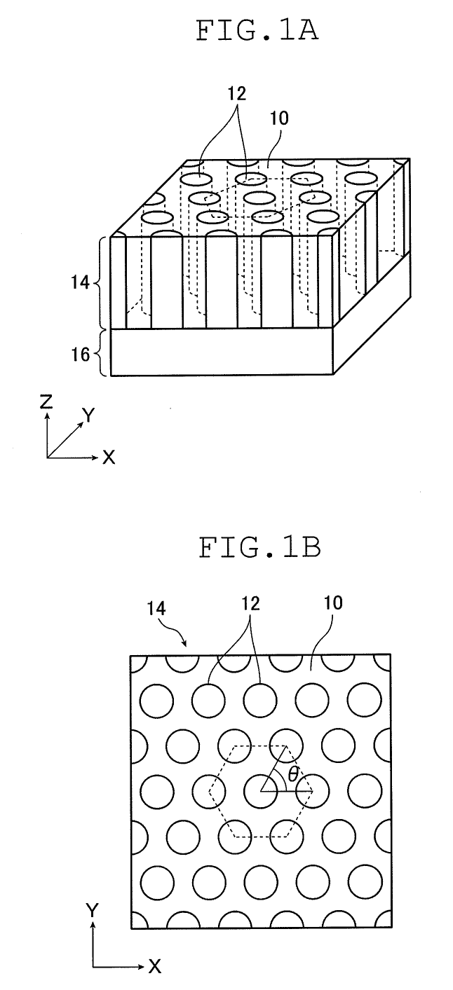

FIG. 1 shows a schematic cross-sectional diagram of the applied film obtained from Step 1. As shown in FIG. 1, the film has a microphase-separated morphology composed of a continuous phase 10 and cylindrical microdomains 12, and is situated on the surface of a substrate 16. As explained above, in the present invention, the continuous phase 10 is composed primarily of the water-insoluble polymer A of the block copolymer, and the cylindrical microdomains 12 are composed primarily of the water-soluble polymer B of the block copolymer and the water-soluble homopolymer B′. The cylindrical microdomains 12 are distributed within the continuous phase 10 and oriented perpendicularly (substantially perpendicular) to the substrate 16 in the Z-axis direction in FIG. 1A. As shown in FIG. 1B, the cylindrical microdomains 12 preferably have a zigzag arrangement in the horizontal plane of the applied film (the plane XY in the diagram), and most preferably form an ordered array having a hexagonal pattern. Here, “hexagonal” denotes a morphology in which the angle θ between one microdomain and two adjacent microdomains is substantially 60 degrees (where “substantially 60 degrees” means between 50 and 70 degrees, and preferably between 55 and 65 degrees). The ordered array of microdomains, although exemplified here by assuming a hexagonal pattern, is not limited to this arrangement. For example, there are also cases in which the ordered array of microdomains assumes a square arrangement. Nor are the cylindrical microdomains 12 limited to being arranged in an ordered pattern; cases in which the cylindrical microdomains 12 are arranged in a non-ordered pattern are also encompassed by the invention.

The size (average diameter) of the cylindrical microdomains 12 may be suitably controlled by, for example, the molecular weights of the block copolymer and the water-soluble homopolymer B′ used, and is preferably between 1 and 250 nm, and more preferably between 10 and 100 nm. If the cylindrical microdomains 12 have a shape that is elliptical, the major axis of the ellipse should fall within the above range. The distance between mutually neighboring microdomains (distance between the center axes) may be suitably controlled by means of, for example, the molecular weight of the block copolymer or the water-soluble homopolymer B′ used, and is preferably between 1 and 300 nm, and more preferably between 10 and 150 nm. The size of the microdomains and the distance between the microdomains can be measured by examination with a microscope, such as an atomic force microscope.

The term ‘microdomain’ is commonly used to denote the domains in a multiblock copolymer, and is not intended here to specify the size of the domains.

The cylindrical microdomains 12 are oriented perpendicularly to the film surface, and are preferably substantially perpendicular. The expression ‘substantially perpendicular’ here denotes that the center axes of the cylindrical microdomains are inclined to the normal of the film surface at an angle of not more than ±45°, and preferably not more than ±30°. The angle of inclination can be measured by the TEM analysis of ultrathin sections, small-angle x-ray diffraction analysis, or some other suitable technique.

In the film 14, the continuous phase 10 is composed primarily of the water-insoluble polymer A of the block copolymer. Here, “composed primarily” signifies that the water-insoluble polymer A in the continuous phase 10 accounts for preferably at least 80 wt %, and more preferably at least 90 wt %, of the total weight of the continuous phase 10. The upper limit is 100 wt %.

The cylindrical microdomains 12 distributed within the continuous phase are composed primarily of the water-soluble polymer B of the block copolymer and the water-soluble homopolymer B′. Here, “composed primarily” signifies that the water-soluble polymer B of the block copolymer and the water-soluble homopolymer B′ in the cylindrical microdomains 12 together account for preferably at least 80 wt %, and more preferably at least 90 wt %, of the total weight of the cylindrical microdomains 12. The upper limit is 100 wt %.

### Step 2

Step 2 is the step of removing the water-soluble homopolymer B′ within the applied film with water. This step removes only the water-soluble homopolymer B′ from the applied film obtained in Step 1, thereby giving a porous film having a plurality of pores of cylindrical shape which are oriented perpendicular to the film surface.

The method of rinsing with water to remove the water-soluble homopolymer B′ is not subject to any particular limitation, so long as it is able to remove the water-soluble homopolymer B′. For example, this may involve using a shower to spray water onto the applied film obtained in Step 1, or dipping the applied film obtained in Step 1 in water. The rinsing step may be carried out a plurality of times. With regard to the rinsing time, optimal conditions are suitably selected according to the material used and other considerations. Following Step 2, the porous film obtained may be suitably removed from the substrate.

### Porous Film

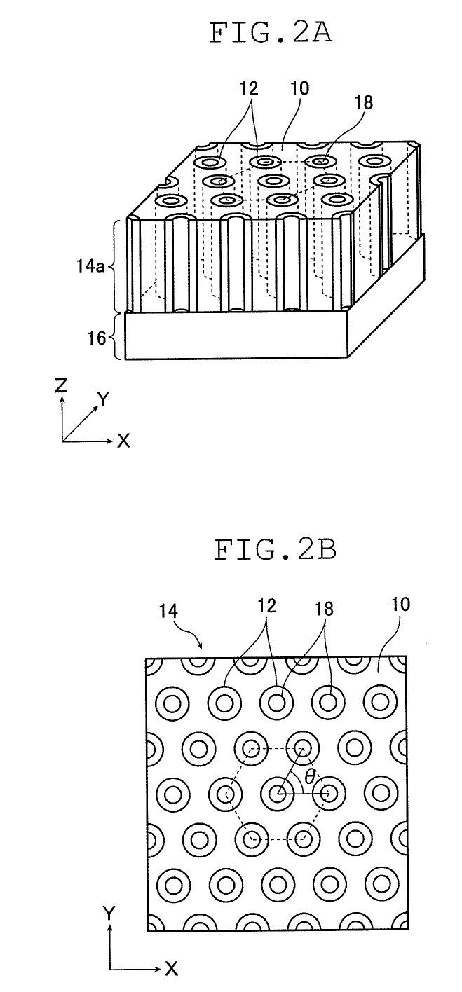

The above-described manufacturing steps yield a porous film which has a microphase-separated morphology made up of a continuous phase composed primarily of a water-insoluble polymer A and cylindrical microdomains which are composed primarily of a water-soluble polymer B, are distributed within the continuous phase and are oriented perpendicular to the film surface. This porous film contains, within the cylindrical microdomains, pores of cylindrical shape and an average diameter of between 1 and 200 nm. FIG. 2, which shows schematic diagrams of the porous film obtained in the present invention, depicts in particular a multilayered body having a substrate 16 and the above-described porous film 14a. In a microphase-separated morphology having a continuous phase 10 composed primarily of the water-insoluble polymer A and having cylindrical microdomains 12, pores 18 are present within the cylindrical microdomains 12. As is apparent from FIG. 2, the water-soluble polymer B which forms the cylindrical microdomains 12 is present on the walls of the pores 18. Also, in FIG. 2, the pores are shown as throughholes, but are not limited to this form.

The porous film is composed of the water-insoluble polymer A and the water-soluble polymer B, but the water-soluble polymer B is present as the primary component on the pore inner walls. That is, the pore inner walls are covered by the water-soluble polymer B, which differs in function from the water-insoluble polymer A making up the continuous phase of the porous film. The water-soluble polymer B functionalizes the pore inner walls.

With ion etching and other conventional methods for dissolving the microdomains serving as one of the phases to obtain a porous film, all of the components making up the microdomains are dissolved and removed, leaving behind only the component making up the continuous phase. That is, the component making up the continuous phase ends up being present on the pore inner walls. Hence, to impart the pore walls with a nature and function that differ from the nature of the component making up the continuous phase, the additional step of chemically modifying the pore inner walls must be taken. Yet, because the pores are very small, complete chemical modification of the entire surface of the pore walls is very difficult to achieve. On the other hand, if, according to the method of the present invention, the water-insoluble polymer A having excellent mechanical strength is used as the continuous phase (support) of the porous film and desired functional molecules are supported on the water-soluble polymer B in the block copolymer used, the pore inner walls can be easily functionalized as desired.

As noted above, the present invention provides a porous film which has a plurality of pores of cylindrical shape oriented perpendicular to the film surface, and which is composed of a water-insoluble polymer A and a water-soluble polymer B that are mutually incompatible. The porous film of the invention has, on the inner walls of the pores, a layer which is composed primarily of the water-soluble polymer B. The layer composed primarily of the water-soluble polymer B has a thickness which can be suitably controlled by the size of the microdomains and the subsequently described size of the pores.

### Pore Size

The average size of the pores in the porous film of the invention (in cases where the planar shape of the pores is circular, the pore diameter) may be suitably controlled by means of, for example, the relative proportions of the block copolymer and the water-soluble homopolymer B′, and is typically between 1 nm and 200 nm, more preferably between 5 nm and 150 nm, and even more preferably between 10 nm and 100 nm. A porous film having a pore size within the above range is better suited for use as a membrane for protein separation or as an etching mask. In cases where the pores are elliptical, the dimension of the major axis should fall within the above range.

Generally, the pores have an average size which is smaller than the size (average diameter) of the above-described microdomains, and water-soluble polymer B is present on the inner walls of the pores. The difference in size between the two (the pores and the microdomains) is preferably between 10 nm and 200 nm. As used herein, “average pore diameter” is a value obtained by measuring the diameters of at least two, and preferably at least ten, randomly selected pores on a porous film surface examined in a scanning electron microscope (SEM) image (over a field of about 1,000 nm×1,000 nm), and calculating the arithmetic mean of the measurements. Use may also be made of a value derived by image processing with a computer.

### Pore Density

The pore density in the porous film of the invention can be suitably controlled by varying the amounts of, for example, the block copolymer and the water-soluble homopolymer B′ used. The pore density is preferably between 2 and 2,500 pores/μm², and more preferably between 10 and 1,500 pores/μm². Within the above range, the degree of order of the pores obtained is further improved.

The pore density specified for the porous film of the present invention is defined as the pore density obtained by using a scanning electron microscope or the like to take a photograph of the surface of the porous film at a magnification that allows pores to be clearly identified, counting the pores in the micrograph, and calculating the number of pores per square micrometer. It is preferable to carry out such a count over as wide an area as possible, such as in a plurality of regions, and calculate an average of the results. The number of pores within a microdomain is not subject to any particular limitation, although it is preferable for each microdomain to have a single pore present therein.

### Pore Depth

The depth of the pores in the porous film of the invention, which can be suitably controlled by the rinsing method in the above-described water rinsing step, is preferably at least 1 nm, and more preferably at least 10 nm. The upper limit in the pore depth is the thickness of the porous film. It is most preferable for the pores to be throughholes. As used herein, “pore depth” refers to the depth of the pores from the surface of the porous film, and can be measured by a technique such as cross-sectional SEM analysis.

### Orientation

The pores in the porous film of the invention, from the standpoint of use in such applications as separation membranes and etching masks, are preferably oriented perpendicular to the film surface, and are more preferably substantially perpendicular. The expression ‘substantially perpendicular’ here signifies that the center axes of the pores are inclined to the normal of the film surface at an angle of not more than ±45°, and preferably not more than ±30°. The angle of inclination can be measured by the TEM analysis of ultrathin sections, small-angle x-ray diffraction analysis, or some other suitable technique.

### Film Thickness

The average thickness of the porous film of the invention may be suitably controlled by varying the amounts of, for example, the block copolymer and the water-soluble homopolymer B′ used, although the thickness is preferably between 10 nm and 1,000 nm, and more preferably between 50 nm and 500 nm. Within this range, the orderliness of the resulting pores is further enhanced. The layer thickness is obtained by taking measurements at three random points on the film surface with a profiler (KLA-Tencor Corp.), and calculating the arithmetical mean of the measurements.

### Arrangement

The arrangement of pores in the porous film of the invention may be suitably controlled by such factors as the types and molecular weights of the block copolymer and the water-soluble homopolymer B′ used, although it is preferable for mutually neighboring pores to have a zigzag arrangement. The zigzag arrangement is preferably an arrangement in which the angle θ between one pore and two adjoining pores is substantially 60 degrees. Here, “substantially 60 degrees” means between 50 and 70 degrees, and preferably between 55 and 65 degrees. In cases where the pores assume an ordered array such as the above in the porous film, it is not necessary for all the pores to be part of such an ordered array. That is, the pores in the porous film may form both an ordered array (e.g., a hexagonal array) and a disordered array. It is advantageous for at least 50%, and preferably at least 60%, of all the pores to have an ordered array.

The average spacing between neighboring pores (distance between the center axes of the pores) may be suitably controlled by means of, for example, the types and molecular weights of the block copolymer and the water-soluble homopolymer B′ used, although the average spacing is preferably between 1 nm and 300 nm, and more preferably between 10 nm and 150 nm. The average pore spacing is a value obtained by measuring the spacing from at least two, and preferably at least ten, randomly selected pores to neighboring pores on a porous film surface examined in a scanning electron microscope (SEM) image (over a field of about 1,000 nm×1,000 nm), and calculating the arithmetic mean of the measurements.

### Applications

The porous film of the invention may be used in a wide variety of applications. Examples of such applications include electronic information recording media, adsorbents, nanoscale reaction site membranes, separation membranes, and polarizing plate-protecting films in liquid-crystal displays and plasma displays.

Of these, because a feature of the porous films obtained according to the invention is that the film surface has throughholes covered with a water-soluble (hydrophilic) polymer, they may be advantageously used as functional separation membranes for separating substances in an aqueous medium. In particular, when a polymer having a protein adsorption suppressing ability is used as the water-soluble polymer component, the porous film can be advantageously used as a separation membrane having an adsorption suppressing ability with respect to other biopolymers such as proteins, cells and the like. Preferred examples of polymers with an adsorption suppressing ability with respect to proteins include polyethylene glycol and phosphoric acid group-containing polymethacrylates with a phospholipid-like structure, such as poly(2-methacryloxyethylphosphorylcholine).

One known method for separating proteins is gel electrophoresis (Tanpakushitsu handobukku [Protein Handbook], by G. Walsh, translated into Japanese by Hirayama et al., p. 167). However, this technique often results in denaturation of the proteins. Moreover, extracting the proteins from the gel is not easy.

Another method that has been mentioned in the literature is a technique which uses a hollow fiber membrane to separate proteins (JP 2006-89468 A). It has been reported that proteins having a molecular weight of up to 60 kDa, which are useful as marker proteins, can be selectively concentrated using this technique. However, this technique requires the use of elaborate equipment and is thus undesirable from the standpoint of cost and industrial applicability. Moreover, proteins cannot be easily separated in this way. In addition, because the hollow fiber membrane surface employed in such a technique has been created without taking into particular consideration the protein adsorption suppressing ability, it ends up adsorbing proteins with use.

When trying to separate biopolymers such as proteins based on differences in size, it would be desirable for the separation membrane to have nanometer-size pores (preferably about 200 nm or less, and most preferably about 100 nm or less), and for the pore surfaces to be covered with a compound having the ability to suppress the adsorption of proteins and the like. However, such separation membranes have not been achieved to date. By using the above-described porous film manufacturing method according to the invention, a porous film in which the inner walls of nanometer-size pores are covered with a compound (e.g., a biocompatible polymer such as a polyethylene glycol or a phosphoric acid group-containing polymethacrylate having a phospholipid-like structure (e.g., poly(2-methacryloxyethylphosphorylcholine)) having the ability to suppress the adsorption of proteins and the like can easily be obtained. A polymer having an excellent mechanical strength (e.g., polystyrene) may be used as the continuous phase (support) of the porous film in order to confer mechanical properties suitable for a medical material.

In conventional processes, following fabrication of the porous film, a step in which the pores are covered with a compound having a specific function has been required. Moreover, given the small size of the openings in the pores, it has been difficult to have chemical modification in this way proceed to completion. Moreover, even when such coating has been carried out successfully, the applied coat within the pores sometimes delaminates during use of the film as a separation membrane. By contrast, in the present invention, as described above, the inner walls of the pores can be coated with a desired functional compound. Moreover, because this compound is covalently bonded with the continuous phase of the porous film, problems such as delamination substantially do not arise during use.

Another preferred application of the porous film of the invention is use as an etching mask for the formation of a specific pattern on a substrate. By using the porous film of the invention as an etching mask, it is possible to form on a substrate surface a specific patterned topography controlled at the nanometer level.

More specifically, methods of manufacturing substrates having recessed features on the surface using the porous film of the invention, while not subject to any particular limitation, preferably include primarily the following three steps.
Step 1: Forming the porous film of the invention on a substrate.
Step 2: Etching the substrate using the porous film as a mask so as to form recessed features on a surface of the substrate.
Step 3: Removing the porous film remaining on the substrate.

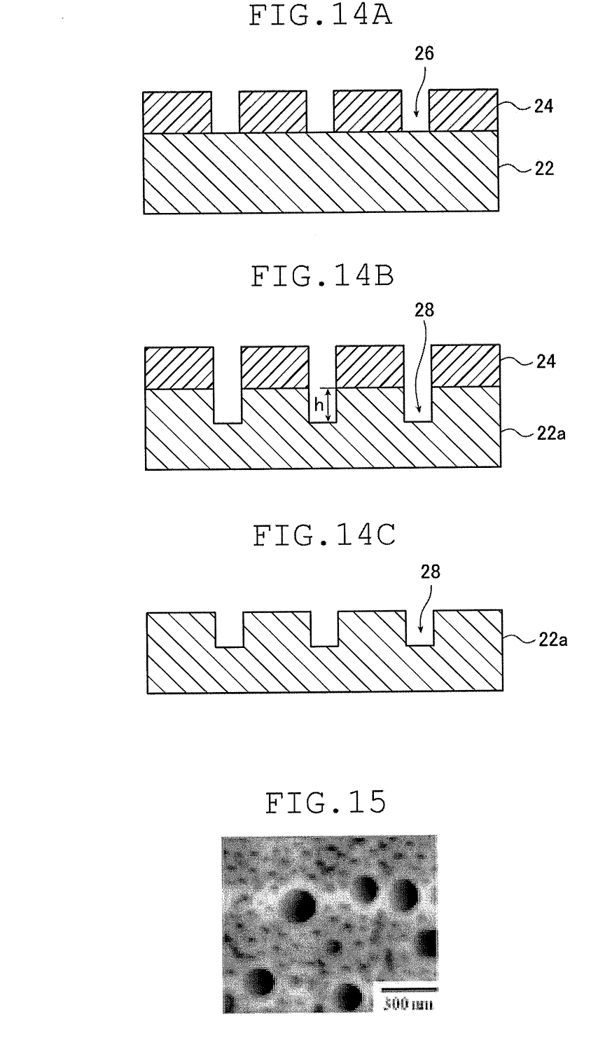

Each of the above steps is described below in conjunction with FIG. 14.

### Porous Film-Forming Step

The porous film forming step is a step in which the above-described porous film having nanometer-size pores is formed on a substrate. By means of this step, as shown in FIG. 14A, a porous film 24 having pores 26 is formed on the substrate 22. The size of the pores 26, as noted above, is between about 1 nm and 200 nm. The thickness of the porous film 24 is not subject to any particular limitation. However, for ease of removal and to facilitate control of the substrate etching depth, the thickness is preferably between 30 nm and 1,000 nm, and more preferably between 50 nm and 750 nm.

The method of forming the porous film on the substrate is not subject to any particular limitation. As explained in the above-described porous film manufacturing method, the porous film may be formed by coating a solution containing a block copolymer and a water-soluble homopolymer B′ onto the substrate, then removing the water-soluble homopolymer B′ with water. Another method of formation that may be used is to deposit a fabricated porous film directly on the substrate.

The substrate to be etched is not subject to any particular limitation; an optimal substrate may be suitably selected according to the purpose of use. Illustrative examples of substrates that may be used include polymer substrates, glass substrates, quartz substrates, and semiconductor substrates (e.g., Group III to V compound semiconductor substrates such as GaAs, GaP, GaN, AlN, InN, InP, InAs, AlAs, GaSb and GaInNAs; silicon, and doped silicon). Of these, quartz substrates and semiconductor substrates are preferred.

When a porous film is fabricated by applying a solution containing the block copolymer and the water-soluble homopolymer B′ onto a substrate, the substrate surface exhibits a contact angle with water of between 40° and 110°.

The substrate shape is not subject to any particular limitation, although the substrate preferably is a dimensionally stable sheet-like object. No particular limitation is imposed on the thickness of such a sheet-like object.

### Etching Step

In the etching step carried out after the porous film-forming step, the substrate is selectively etching using the porous film as the mask, thereby forming recessed features on the surface of the substrate. By means of this step, as shown in FIG. 14B, the substrate material positioned at the pores is etched away, thereby giving a substrate 22a having a plurality of recesses 28.

The shape of the openings in the recesses 28, while not subject to any particular limitation, is preferably circular, like the shape of the pore openings. In FIG. 14B, the recesses 28 are shown to be cylindrical in shape, although the shape of the recesses 28 is not limited to this and may instead be conical.

The average diameter of the openings in the recesses 28 is suitably adjusted by controlling the etching conditions. However, to enhance the light extraction efficiency from the resulting substrate (e.g., semiconductor substrate), the average diameter is preferably between 50 nm and 200 nm, and more preferably between 75 nm and 200 nm. In the recesses 28, it is preferable for the sidewalls (inner walls) of the recesses 28 to be formed so as to be substantially parallel in the thickness direction of the substrate 22. The depth (height) h of the recesses 28 is suitably adjusted by controlling the etching conditions, although from the standpoint of use in various applications, the depth is preferably between 10 nm and 1,000 nm, and more preferably between 30 nm and 750 nm.

The number of recesses 28, while not subject to any particular limitation, generally corresponds to the number of pores 26 in the porous film 24 and is preferably between 2 and 2,500 recesses/μm², and more preferably between 10 and 1,500 recesses/μm².

The etching conditions are not subject to any particular limitation so long as the substrate can be etched, although treatment optimal for the type of substrate is typically carried out. Examples include wet etching processes in which etching is carried out with an etchant such as sulfuric acid, nitric acid, phosphoric acid or hydrofluoric acid; and dry etching processes such as reactive ion etching or reactive gas etching. Of these, dry etching is preferred because the etching depth is easy to control. The etching gas may be suitably selected according to the substrate. For example, etching may be carried out using a fluorinated etching gas such as CF₄, NF₃ or SF₆, or a chlorinated etching gas such as Cl₂ or BCl₃.

The etching treatment time may be suitably adjusted according to the intended use of the substrate, although to facilitate control of the etching depth, the etching time is preferably between 5 and 300 seconds, and more preferably between 10 and 200 seconds.

To selectively etch the substrate during the etching step, use is made of the difference between the substrate and the porous film in their respective dry etching rates, degradability on exposure to irradiation, or thermal degradability.

### Removal Step

The removal step carried out after the etching step is a step in which the porous film that was used as the mask in the etching step and remains on the substrate is removed to give a substrate having recessed features thereon. As shown in FIG. 14C, when the porous film is removed, a substrate 22a having a plurality of recesses 28 therein is obtained.

The method used to remove the porous film is not subject to any particular limitation. Examples include treatment with a solvent that dissolves the porous film, and removal by etching.

The substrate having recesses in the surface that is obtained by the above-described process may be employed in various applications. For example, when a semiconductor substrate is used as the substrate, the light extracting efficiency from the substrate side (light extracting side) of the substrate provided with recesses is improved, enabling use in various types of lighting components.

### EXAMPLES

Examples of the invention are provided below by way of illustration and not by way of limitation.

The subsequently described atomic force microscope (AFM) observations were carried out with a SPA-400 system (Seiko Instruments, Inc.) in the tapping mode. Scanning transmission electron microscope (STEM) observations were carried out using an S5200 system (Hitachi High-Technologies Corporation). The thicknesses of the porous films obtained were measured using a profiler (KLA-Tencor Corp.).

### Example 1

This example relates to the substrate contact angle and the ability or inability to fabricate a porous film having pores with a cylindrical shape.

### Fabrication of Sample 1

An investigation was carried out using as the block copolymer an A-B type block copolymer composed of polystyrene (water-insoluble polymer A) and polyethylene glycol (water-soluble polymer B) acquired from Polymer Source, Inc. (P3799-SEO). In P3799-SEO, the polystyrene portion had a weight-average molecular weight (Mw) of 225,000, the polyethylene glycol portion had a weight-average molecular weight (Mw) of 26,000, and Mw/Mn=1.12. The water-soluble homopolymer B′ was a polyethylene glycol homopolymer (weight-average molecular weight (Mw), 600; referred to below as “PEG 600”) purchased from Tokyo Kasei Kogyo Co., Ltd.

A quartz substrate was immersed for 24 hours in a 1 wt % toluene solution of ethyldimethylchlorosilane (Gelest, Inc.), following which the quartz substrate was rinsed three times with 2 mL of toluene and dried (by blowing compressed air), and used in the present experiment. The contact angle with water of the substrate surface before and after silane coupling treatment was measured to determine whether surface modification had been achieved. The contact angle of the non-surface-modified substrate was 18±7°, and the contact angle of the silane coupling agent-treated substrate was 93±6°. The latter value being a standard contact angle following alkylation, surface modification was confirmed to have taken place.

A mixed solution (200 μL) of P3799-SEO (250 mg) and PEG 600 (80 mg) dissolved in toluene (9.67 g) was spin-coated onto the above substrate under specific conditions (slope, 5 seconds; 3,000 rpm; 90 seconds) to form an applied film. Here, “slope, 5 seconds” signifies the length of time until the spin rate reaches 3,000 rpm. This film was then subjected to 72 hours of aging at room temperature and under saturated toluene conditions. Atomic force microscopic (AFM) measurement was carried out, whereupon a microphase-separated morphology in which cylindrical microdomains are oriented perpendicular to the film surface was confirmed to have been achieved. Next, the film was rinsed five times with 2 mL of deionized water, thereby giving Sample 1. From the definitions of formulas (1) and (2), the M(b1)/M(b2) (abbreviated below as “r”) value of Sample 1 was 43, and the a1/(a1+b1+b2) (abbreviated below as “f(a)”) value was 0.71.

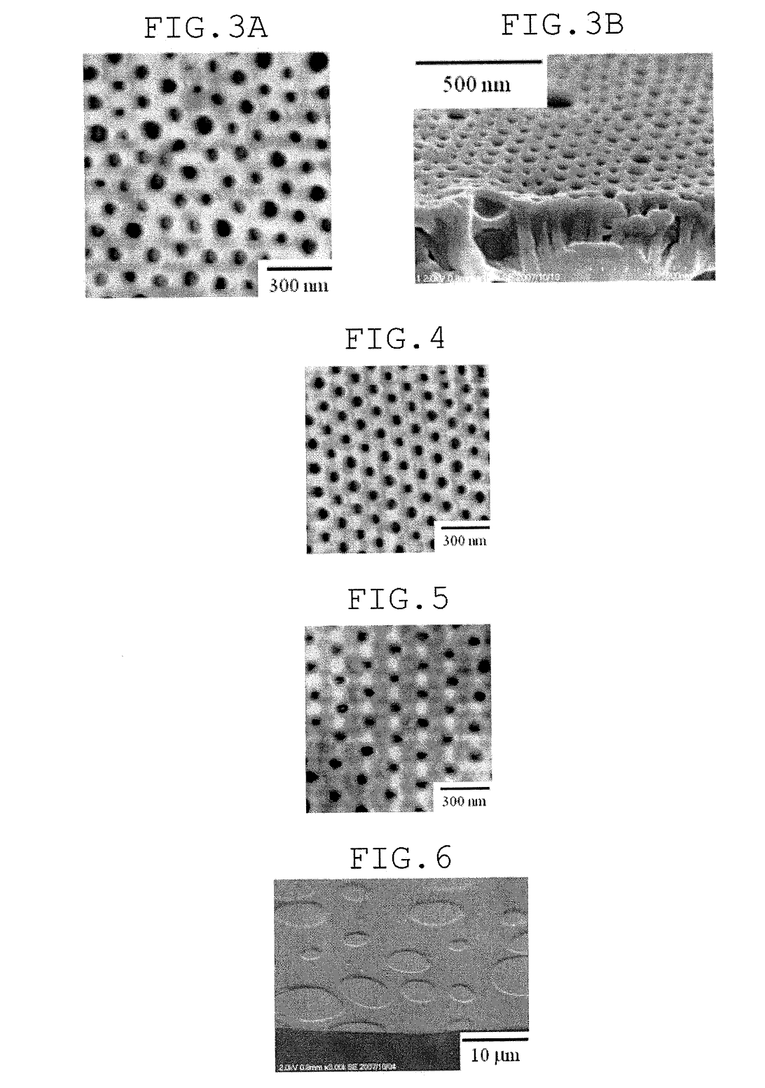

AFM observation was carried out to confirm the surface morphology of Sample 1 (FIG. 3A). Pores having an average pore diameter of 50 nm were found to be hexagonally distributed. In addition, to confirm the three-dimensional morphology, Sample 1 was fractured in liquid nitrogen and examined under a scanning electron microscope (SEM), whereupon it was confirmed that throughholes which reach the quartz substrate were obtained (FIG. 3B). The pore density was 84 pores/μm², and the average spacing between neighboring pores was 106 nm. Sample 1 had an average film thickness of 280 nm.

### Fabrication of Sample 2

A quartz substrate was immersed for 24 hours in a 1 wt % toluene solution of octadecyltrimethoxysilane (Gelest, Inc.) then rinsed three times with 2 mL of toluene and dried (drying conditions: compressed air was used), and the resulting substrate was used in the present experiment. The contact angle of the non-surface-modified substrate was 18±7°, and the contact angle of the silane coupling-treated substrate was 103±6°. The latter value being a standard contact angle following alkylation, surface modification was confirmed to have taken place. Aside from using this substrate, the same procedure was carried out as in the fabrication of Sample 1, thereby giving Sample 2.

From the results of AFM examination of Sample 2, a microphase-separated morphology in which cylindrical microdomains are oriented perpendicular to the film surface was confirmed. Also, the pores, which had an average pore diameter of 61 nm, were confirmed to be hexagonally arranged (FIG. 4).

### Fabrication of Sample 3

A solution (200 μL) of polyhydroxystyrene (200 mg; abbreviated below as “PHS”) dissolved in ethanol (9.8 g) was spin-coated onto a slide glass substrate (slope, 5 seconds; 3,000 rpm; 90 seconds). The contact angle of resulting substrate was 60±7°. Aside from using this substrate, the same procedure was carried out as in the fabrication of Sample 1, thereby giving Sample 3.

From the results of AFM examination of Sample 3, a microphase-separated morphology in which cylindrical microdomains are oriented perpendicular to the film surface was confirmed. Also, the pores, which had an average pore diameter of 80 nm, were confirmed to be hexagonally arranged (FIG. 5).

### Fabrication of Sample 4

Aside from using an unmodified quartz substrate (contact angle: 18±5°), the same procedure was carried out as in the fabrication of Sample 1, thereby giving Sample 4. Sample 4 was fractured in liquid nitrogen and subjected to SEM examination, whereupon macroscale pores were found to be present. The desired porous film was not obtained (FIG. 6).

### Fabrication of Sample 5

A quartz substrate was immersed for 24 hours in a 1 wt % toluene solution of perfluorodecyltriethoxysilane (Gelest, Inc.) then rinsed three times with 2 mL of toluene and dried (drying conditions: compressed air was used), and the resulting substrate was used in the present experiment. The contact angle of the non-surface-modified substrate was 18±7°, and the contact angle of the silane coupling-treated substrate was 112°. The latter value being a standard contact angle following fluorination, surface modification was confirmed to have taken place. Aside from using this substrate, the same procedure was carried out as in the fabrication of Sample 1, thereby giving Sample 5. At the time of coating, the solution was repelled and could not be uniformly applied to the substrate, as a result of which the desired porous film was not obtained.

Results for the contact angle dependency of Samples 1 to 3 are given in Table 1 below.

TABLE 1

| | | | Contact | | | |
|---|---|---|---|---|---|---|
| | | | angle | | | Fabricability |
| | Substrate | Surface modifying agent | (°) | r | f (a) | (Yes/No) |
| Sample 1 | Quartz | Ethyldimethylchlorosilane | 93 | 43 | 0.71 | Yes |
| Sample 2 | Quartz | Octadecyltrimethoxysilane | 103 | 43 | 0.71 | Yes |
| Sample 3 | Quartz | Polyhydroxystyrene | 60 | 43 | 0.71 | Yes |
| Sample 4 | Quartz | — | 18 | 43 | 0.71 | No |
| Sample 5 | Quartz | Perfluorodecyltriethoxysilane | 112 | 43 | 0.71 | No |

Cases in which a porous film having pores with the desired cylindrical shape could be fabricated are denoted in the table as “Yes.” Cases in which such a film could not be formed are denoted as “No.”

The above results show that when the contact angle of the substrate to water was within a fixed range, a porous film in which the pores are packed hexagonally and oriented perpendicular to the film surface could be fabricated.

### Example 2

This example shows the relationship between the r value and the fabricability of a porous film having pores with a cylindrical shape.

### Fabrication of Sample 6

Aside from using a polyethylene glycol homopolymer having a weight-average molecular weight (Mw) of 400 (abbreviated below as “PEG 400”) instead of PEG 600, the same procedure was carried out as in the fabrication of Sample 1, thereby giving Sample 6. From the definitions of formulas (1) and (2), the r value was 65 and the f(a) value was 0.71.

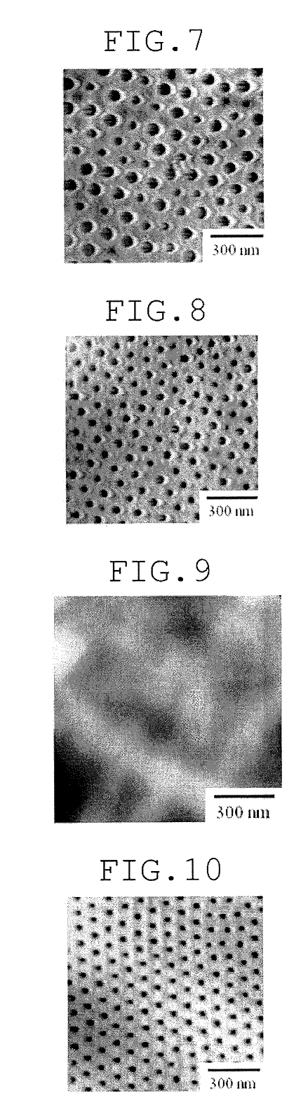

Based on the AFM examination of Sample 6 and other results, a microphase-separated morphology in which cylindrical microdomains are oriented perpendicular to the film surface was confirmed. In addition, pores having an average pore diameter of 42 nm were observed to be hexagonally arranged (FIG. 7).

### Fabrication of Sample 7

Aside from using a polyethylene glycol homopolymer having a weight-average molecular weight (Mw) of 200 (abbreviated below as “PEG 200”) instead of PEG 600, the same procedure was carried out as in the fabrication of Sample 1, thereby giving Sample 7. From the definitions of formulas (1) and (2), the r value was 130 and the f(a) value was 0.71.

Based on the AFM examination of Sample 7 and other results, a microphase-separated morphology in which cylindrical microdomains are oriented perpendicular to the film surface was confirmed. In addition, pores having an average pore diameter of 38 nm were observed to be hexagonally arranged (FIG. 8).

### Fabrication of Sample 8

Aside from using dimethoxyethane (Wako Pure Chemical Industries, Ltd.), which is a polyethylene glycol monomer, instead of PEG 600, the same procedure was carried out as in the fabrication of Sample 1, thereby giving Sample 8. From the definitions of formulas (1) and (2), the r value was 289 and the f(a) value was 0.69.

Based on the AFM examination of Sample 8, the target porous film was not obtained (FIG. 9).

### Fabrication of Sample 9

Aside from using P123-2SEO1 (weight-average molecular weight (Mw) of polystyrene portion, 36,000; weight-average molecular weight (Mw) of polyethylene glycol portion, 1,400; Mw/Mn=1.12) instead of P3799-SEO, the same procedure was carried out as in the fabrication of Sample 1, thereby giving Sample 9. From the definitions of formulas (1) and (2), the r value was 2.3 and the f(a) value was 0.75.

Based on the AFM examination of Sample 9, as with Sample 4, macro-scale phase separation was found to have occurred and the desired porous film was not obtained.

Results for the contact angle dependency of Samples 1 and 6 to 9 are given in Table 2 below.

TABLE 2

| | | | Contact | | | |
|---|---|---|---|---|---|---|
| | | | angle | | | Fabricability |
| | Substrate | Surface modifying agent | (°) | r | f (a) | (Yes/No) |
| Sample 1 | Quartz | Ethyldimethylchlorosilane | 93 | 43 | 0.71 | Yes |
| Sample 6 | Quartz | Ethyldimethylchlorosilane | 93 | 65 | 0.71 | Yes |
| Sample 7 | Quartz | Ethyldimethylchlorosilane | 93 | 130 | 0.71 | Yes |
| Sample 8 | Quartz | Ethyldimethylchlorosilane | 93 | 289 | 0.69 | No |
| Sample 9 | Quartz | Ethyldimethylchlorosilane | 93 | 2.3 | 0.75 | No |

Cases in which a porous film having pores with the desired cylindrical shape could be fabricated are denoted in the table as “Yes.” Cases in which such a film could not be formed are denoted as “No.”

The above results show that when the r value was within a given range, a porous film in which the pores are packed hexagonally and oriented perpendicular to the film surface could be fabricated.

### Example 3

This example shows the relationship between the f(a) value and the fabricability of a porous film having pores with a cylindrical shape.

### Fabrication of Sample 10

Aside from changing the amount of PEG 600 to 40 mg, the same procedure was carried out as in the fabrication of Sample 1, thereby giving Sample 10. From the definitions of formulas (1) and (2), the r value for Sample 10 was 43 and the f(a) value was 0.80.

Based on the AFM examination of Sample 10 and other results, a microphase-separated morphology in which cylindrical microdomains are oriented perpendicular to the film surface was confirmed. In addition, pores having an average pore diameter of 42 nm were observed to be hexagonally arranged (FIG. 10). To confirm the three-dimensional morphology, Sample 10 was fractured in liquid nitrogen and subjected to SEM examination. It was confirmed from SEM examination that throughholes which reach the quartz substrate were obtained. This demonstrated that pore size control of the throughholes by controlling the amount of homopolymer added within the range of the invention is possible. The pore density was 156 pores/μm², and the average spacing between neighboring pores was 92 nm. Sample 10 had an average film thickness of 271 nm.

### Fabrication of Sample 11

Aside from changing the amount of PEG 600 to 20 mg, the same procedure was carried out as in the fabrication of Sample 1, thereby giving Sample 11. From the definitions of formulas (1) and (2), the r value for Sample 11 was 43 and the f(a) value was 0.85.

Based on the AFM examination of Sample 11 and other results, a microphase-separated morphology in which cylindrical microdomains are oriented perpendicular to the film surface was confirmed. In addition, pores having an average pore diameter of 35 nm were observed to be hexagonally arranged (FIG. 11). To confirm the three-dimensional morphology, Sample 11 was fractured in liquid nitrogen and subjected to SEM examination. It was confirmed from SEM examination that throughholes which reach the quartz substrate are obtained. This demonstrated that pore size control of the throughholes by controlling the amount of homopolymer added within the range of the invention is possible. The pore density was 225 pores/μm², and the average spacing between neighboring pores was 82 nm. Sample 11 had an average film thickness of 260 nm.

### Fabrication of Sample 12

Aside from changing the amount of PEG 600 to 500 mg, the same procedure was carried out as in the fabrication of Sample 1, thereby giving Sample 12. From the definitions of formulas (1) and (2), the r value for Sample 12 was 43 and the f(a) value was 0.32.

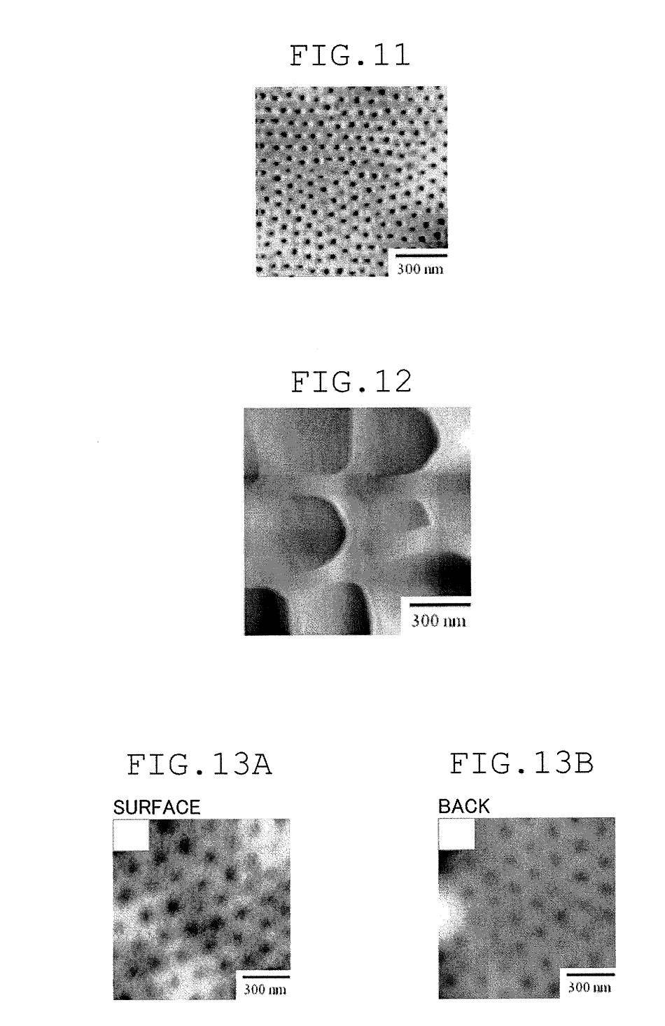

Based on the AFM examination of Sample 12 and other results, instead of the hexagonal packing of pores of relatively uniform diameter observed in Samples 1, 2 and elsewhere, a surface in which pores having an average size of 300 nm are present in an disordered array was observed. Hence, the desired porous film was not obtained (FIG. 12).

### Fabrication of Sample 13

Aside from changing the amount of PEG 600 to 0.5 mg, the same procedure was carried out as in the fabrication of Sample 1, thereby giving Sample 13. From the definitions of formulas (1) and (2), the r value for Sample 12 was 43 and the f(a) value was 0.91.

Based on the SEM examination of Sample 13 and other results, pores were not observed and so the desired porous film was not obtained.

Results for the f(a) value dependency of Samples 1 and 10 to 13 are given in Table 3 below.

TABLE 2

| | | | Contact | | | |
|---|---|---|---|---|---|---|
| | | | angle | | | Fabricability |
| | Substrate | Surface modifying agent | (°) | r | f (a) | (Yes/No) |
| Sample 1 | Quartz | Ethyldimethylchlorosilane | 93 | 43 | 0.71 | Yes |
| Sample | Quartz | Ethyldimethylchlorosilane | 93 | 43 | 0.8 | Yes |
| 10 | | | | | | |
| Sample | Quartz | Ethyldimethylchlorosilane | 93 | 43 | 0.85 | Yes |
| 11 | | | | | | |
| Sample | Quartz | Ethyldimethylchlorosilane | 93 | 43 | 0.32 | No |
| 12 | | | | | | |
| Sample | Quartz | Ethyldimethylchlorosilane | 93 | 43 | 0.91 | No |
| 13 | | | | | | |

Cases in which a porous film having pores with the desired cylindrical shape could be fabricated are denoted in the table as “Yes.” Cases in which such a film could not be formed are denoted as “No.”

The above results show that when the f(a) value was within a given range, a porous film in which the pores are packed hexagonally and oriented perpendicular to the film surface could be fabricated.

### Example 4

This example illustrates a case in which Sample 3 was immersed in ethanol, thereby dissolving polyhydroxystyrene, and delaminating the porous film from the substrate.

FIGS. 13A and B show AFM images of the surface (exposed side) and back (substrate side) of the porous film following delamination. Based on the results of AFM examination, pores having about the same average pore diameter (78 nm) on both the surface and back of the film were observed to be hexagonally arranged.

It was found from the above results that the pores passed through the porous film from the surface (exposed side) to the back (substrate side) thereof.

### Example 5

This example illustrates a case in which the porous film of the invention was used as a mask during etching.

### Fabrication of Sample 14 and Substrate 1

A 1 wt % toluene solution of PS-r-PMMA (Polymer Source, Inc.; P3437-SMMAranOHT) was spin-coated onto a silicon wafer and annealed at 140° C. for one day, thereby fabricating a modified silicon wafer. The modified silicon wafer had a contact angle with water of 82±8°.

A toluene solution (200 μL) containing 0.5 wt % of P3799-SEO and 0.16 wt % of PEG 600 was spin-coated onto the above substrate under specific conditions (slope, 5 seconds; 3,000 rpm; 90 seconds) to form an applied film. This film was then subjected to 72 hours of aging at room temperature and under saturated toluene conditions. AFM measurement and the like was carried out, whereupon a microphase-separated morphology in which cylindrical microdomains are oriented perpendicular to the film surface was confirmed to have been achieved. The film was then rinsed five times with 2 mL of deionized water, thereby giving Sample 14. From the definitions of formulas (1) and (2), the r value of Sample 14 was 43, and the f(a) value was 0.71.

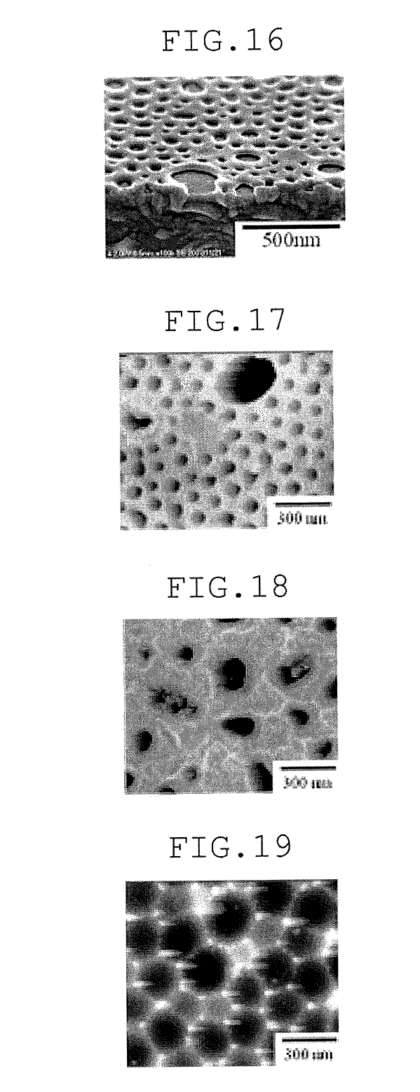

AFM examination was carried out to confirm the surface morphology of Sample 14. Pores having an average pore diameter of 70 nm were observed (FIG. 15). In addition, to confirm the three-dimensional morphology, SEM examination was carried out, whereupon it was confirmed that throughholes which reach the quartz substrate were obtained (FIG. 16). The pore density was 83 pores/μm², and the average spacing between neighboring pores was 130 nm. Sample 14 had an average film thickness of 80 nm.

The resulting Sample 14 was etched with a RIE dry etching system. The etching conditions were as follows: etching gas, SF₆; output, 150 W; etching time, 32 seconds. Following etching treatment, the resulting sample was immersed in toluene and ultrasonically cleaned to remove the porous film, thereby fabricating a Substrate 1 having recessed features on the surface. The resulting Substrate 1 was examined under an atomic force microscope (FIG. 17), whereupon recesses having a depth of 65 nm and an average diameter at the opening of 80 nm were found to have formed on the substrate surface at a density of 80 recesses/μm².

### Fabrication of Substrate 2

Aside from changing the etching time to 16 seconds, a Substrate 2 having recessed features on the surface was fabricated by the same procedure as that used in the production of Substrate 1. The resulting Substrate 2 was examined under an atomic force microscope (FIG. 18), whereupon recesses having a depth of 42 nm and an average diameter at the opening of 150 nm were found to have formed on the substrate surface at a density of 20 recesses/μm².

### Fabrication of Substrate 3

Aside from changing the etching time to 65 seconds, a Substrate 3 having recessed features on the surface was fabricated by the same procedure as that used in the production of Substrate 1. The resulting Substrate 3 was examined under an atomic force microscope (FIG. 19), whereupon recesses having a depth of 35 nm and an average diameter at the opening of 176 nm were found to have formed on the substrate surface at a density of 33 recesses/μm².

What is claimed is:

1. A porous film comprising a microphase-separated morphologyy comprising
a continuous phase which is composed primarily of a water-insoluble polymer A, and
a plurality of cylindrical microdomains which are composed primarily of a water-soluble polymer B incompatible with the water-insoluble polymer A, distributed within the continuous phase and oriented perpendicular to a surface of the film,
wherein the cylindrical microdomains contain therein pores having a cylindrical shape and an average diameter of between 1 and 200 nm.

2. The porous film of claim 1, wherein the pores have a density of between 2 and 2,500 pores/μm².

3. The porous film of claim 1, wherein the water-soluble polymer B is a biocompatible polymer.

4. The porous film of claim 1, wherein the water-insoluble polymer A is selected from among polystyrenes, poly(meth)acrylates, polybutadienes and polyisoprenes.

5. The porous film of claim 1, wherein the porous film is adapted for use as a mask in an etching operation of a substrate.

6. A method of manufacturing the porous film of claim 1, the method comprising the steps of, in order:
(1) forming a film by coating a substrate surface having a contact angle with water of between 40° and 110° with a solution containing (a) a block copolymer composed of a water-insoluble polymer A and a water-soluble polymer B which are mutually incompatible and (b) a water-soluble homopolymer B′, which film satisfies the following formulas (1) and (2)
5<M(b1)/M(b2)<250 (1)
0.60≦a1/(a1+b1+b2)≦0.90 (2),
where M(b1) represents the weight-average molecular weight of the water-soluble polymer B of the block copolymer, M(b2) represents the weight-average molecular weight of the water-soluble homopolymer B′, a1 represents the volume of the water-insoluble polymer A of the block copolymer in the film, b1 represents the volume of the water-soluble polymer B of the block copolymer in the film and b2 represents the volume of the water-soluble homopolymer B′ in the film; and
(2) removing the water-soluble homopolymer B′ within the film with water.

7. The method of claim 6, wherein the solution has a combined concentration of the block copolymer and the water-soluble homopolymer B′, based on the total weight of the solution, of between 0.1 and 20 wt %.

8. A porous film obtained by a method comprising the steps of, in order:
(1) forming a film by coating a substrate surface having a contact angle with water of between 40° and 110° with a solution containing (a) a block copolymer composed of a water-insoluble polymer A and a water-soluble polymer B which are mutually incompatible and (b) a water-soluble homopolymer B′, which film satisfies the following formulas (1) and (2)
5<M(b1)/M(b2)<250 (1)
0.60≦a1/(a1+b1+b2)≦0.90 (2),
where M(b1) represents the molecular weight of the water-soluble polymer B of the block copolymer, M(b2) represents the molecular weight of the water-soluble homopolymer B′, a1 represents the volume of the water-insoluble polymer A of the block copolymer in the film, b1 represents the volume of the water-soluble polymer B of the block copolymer in the film and b2 represents the volume of the water-soluble homopolymer B′ in the film; and
(2) removing the water-soluble homopolymer B′ within the film with water.

9. A method of manufacturing a substrate having recessed features on a surface thereof, the method comprising the steps of, in order:
(1) forming the porous film of claim 1 on a substrate,
(2) etching the substrate using the porous film as a mask so as to form recessed features on a surface of the substrate, and
(3) removing the porous film remaining on the substrate.

10. The method of claim 9, wherein the substrate is a quartz substrate or a semiconductor substrate.
